(19) United States
(12) Patent Application Publication
(10) Pub. No.: US 2013/0175569 A1
(43) Pub. Date: Jul. 11, 2013

(54) LED Lighting Device

(71) Applicant: Michel Asseraf, Hallandale Beach, FL (US)

(72) Inventor: Michel Asseraf, Hallandale Beach, FL (US)

(21) Appl. No.: 13/121,314

(22) PCT Filed: Jan. 26, 2011
(86) PCT No.: PCT/EP11/51046

§ 371 Date: Apr. 1, 2013

Related U.S. Application Data
(60) Provisional application No. 61/308,456, filed on Feb. 26, 2010.

(30) Foreign Application Priority Data
Jan. 26, 2010 (FR) 1050502
Nov. 2, 2010 (FR) 1059012

(51) Int. Cl. H01L 33/64

(52) U.S. Cl. CPC H01L 33/64
USPC 257/99

(57) ABSTRACT

The invention involves a lighting device (1) with:
A body (2) of transparent or translucent material;
A collar (3) mounted on a first side (22) of the body (2) and delineating a resin-filled first cavity (31);
A lighting element (4) with an electrical light source (41) and associated electrical connections (42).

The electrical light source (41) is partly maintained in the body (2) and the electrical connections are located in the first resin-filled cavity (31).

The lighting device (1) has a first high thermal diffusivity sheet (5) maintained against the first side (22) of the body (2) in order to allow the dissipation of heat generated by the electrical light source, and a regulator (7) maintained against a second high thermal diffusivity sheet (62) to allow the dissipation of heat generated by said regulator (7).

The invention relates to a lighting device, specifically, the invention concerns a lighting device with light-emitting diodes adapted for a use in exposed environments such as in a marine environment.

There are currently a number of lighting devices, which can be used inside or outside. Light-emitting diodes—commonly called LEDs—are increasingly used, primarily due to their low energy consumption and their long life span.

Lighting devices with LEDs are often used for specific applications, for example, fastened to swimming pool walls, boats, etc.

The lighting devices are designed to be waterproof for these applications.

It is therefore common to embed electronic components for the operation of the LEDs in a resin, for example, an epoxy resin.

Although this technical solution is efficient with regard to water tightness it is however unfavorable with regard to the dissipation of heat—albeit at a low level—that is released by the LEDs and the electronic components that are associated thereto, although this waterproof solution has a dampening effect with regard to the increased lighting power using this technology.

There is therefore a need for a suitable lighting device that can supply sufficient power all while being waterproof in a totally immerged situation.

Advantageously, such a device will at the same time have a good impact- and fire-resistance, in order to meet the regulatory requirements concerning the intended applications: swimming pools and boats.

In view of this, a lighting device entails:

A body of transparent or translucent material;

A collar mounted on a first side of the body and by means of this body, delineating a volume filled with a resin;

A lighting element involving a source of light that emits a beam of light associated with electrical connections.

In accordance with the invention, the source of light is partly supported in the body and the electrical connections are located in the resin-filled cavity.

Light source here means any means suitable for generating a beam of light, such as a light-emitting diode, called LED.

Electrical connections here mean metal parts of the lighting element making it possible to connect the source of light to an electric power source.

The volume is advantageously filled with resin. Thus, the lighting device is made waterproof and can be used in restrictive environments, such as a marine environment.

In order to allow the dissipation of the heat generated by the source of light, the lighting device further involves a first sheet with a high thermal distribution maintained against the first side of the body.

The source of light is connected to a regulator placed in the resin-filled cavity.

In order to allow the dissipation of heat generated by the regulator, the lighting device additionally has a second high thermal diffusivity sheet maintained against the regulator.

Thermal diffusion is a property quantified by the quotient between thermal conductivity and the specific heat of a material. It characterizes the suitability of a material to transmit heat by conduction and the facility with which an increase in the temperature in a point of a body comprised of this material is transmitted throughout the entire volume of this body.

Thus, the heat is diffused over the entire surface of the first sheet with a high thermal diffusivity and the temperature near the source of light is lowered. The risk of fire in contact with other products (for example, paper, fabric, plastic, etc.) is negligible.

In accordance with the preferred embodiment, the invention further meets the following characteristics, implemented separately or in each of their technically operative combinations.

In a preferred embodiment, the first sheet with a high thermal diffusivity is constituted of an aluminum-base alloy. These materials in fact have a strong conductivity and a high thermal diffusivity. The alloy will be chosen as a function of its corrosion-resistance in the environment the lighting device is to be used.

In a preferred embodiment, the second sheet with a high thermal diffusivity is constituted of an aluminum alloy.

Advantageously, the source of light has at least one LED. LEDs are very attractive because they are small in dimension, have a high light energy/electrical energy consumption performance and have a long life span.

In order to benefit from a part of its surface in the open, and to more effectively participate in the cooling of the lighting device, the first sheet with a high thermal diffusivity has a surface strictly higher than the maximum transversal dimension of the collar.

Advantageously, to facilitate production of the lighting device, the first high thermal diffusivity sheet covers the back side of the body.

In one embodiment, at least one light-emitting diode is connected directly to a regulator placed on a support in a resin-filled cavity.

The selection of the regulator, on one hand, is to ensure it can withstand 2-amp currents, and on the other, to ensure it requires very few electrical components to operate. Thus, the lighting device does not require a printed circuit board, which makes it possible to noticeably reduce its ultimate thickness.

The support is a sufficiently rigid piece in order to support the regulator. The support also makes it possible to position and maintain the regulator in the resin-filled cavity.

In one embodiment of the support, the support is a rigid plate on whose surface a sheet is maintained that is comprised of an insulating material. Preferably, the surface of this plate on which the sheet in insulating material is maintained is opposite the source of light. This support further involves a second high thermal diffusivity sheet glued to the sheet of insulating material.

The regulator is placed on the second high thermal diffusivity sheet. Thus, the temperature is diffused over the surface of the second high thermal diffusivity sheet and the temperature near the regulator is lowered.

The superposition—in the order indicated—of the two sheets and the position of the regulator on the second sheet with a high thermal diffusivity make it possible on one hand to diffuse the heat of the regulator to the environment outside the lighting device (rather than to the source of light) and on the other, to prevent any electrical contact of the regulator when the support is placed in the collar.

In a preferred embodiment of the support, the sheet in insulating material is sufficiently rigid to form a plate and support the regulator without using the rigid plate. The second sheet with a high thermal diffusivity is glued to the sheet in insulating material on a surface of said insulating material opposite a surface across from the source of light.

In one embodiment, the sheet in insulating material is a sheet in polyester. The insulating polyester sheet prevents the heat thus diffused from being conducted to the support of the LEDs. The heat generated by the regulator is thus diffused to the back of the LEDs.

In another embodiment, to simplify production of the lighting device and to minimize the number of elements necessary for its manufacture, the second high thermal diffusivity sheet is sufficiently rigid to support and maintain the regulator without having to use a rigid plate.

In order to more effectively participate in the cooling of the regulator and consequently the lighting device, the second high thermal diffusivity sheet (62) is preferably positioned at one lateral end, opposite the lateral end located on the back of the body and thus has a side not included in the internal volume of the collar.

According to an advantageous characteristic of the invention, to dissociate the various heat sources, the source of light and the regulator and to prevent heat of the regulator from being conducted to the source of light and back, the collar has two volumes, a first volume that has electrical connections of the source of light, and a second volume with the regulator and the second high thermal diffusivity sheet.

According to an advantageous characteristic of the invention, to allow the dissipation of the heat generated by the source of light in the absence of the body and the first high thermal diffusivity sheet, the collar has—at one lateral end located on the side of the body—a third high thermal diffusivity sheet.

In order to meet mechanical constraints or fulfill a special aesthetic aspect, the body is detachable with respect to the collar. Thus, the body can be interchangeable in its form, color and thickness. The collar and the body can therefore be made independently of each other. The lighting device therefore has the advantage of being a single unit and being able to be delivered with a multitude of interchangeable bodies.

According to an advantageous characteristic of the invention, the lighting device—near one lateral end opposite a lateral end located on the back side of the body—has a plate for dissipating the heat.

In a preferred embodiment, the material constituting the body is a polycarbonate, allowing the lighting device to receive a favorable fire rating and to withstand loads of compression and tension of more than 20,000 Newtons.

The detailed description of the invention is provided with reference to the figures that represent:

FIG. 1, a view from above of a lighting device according to one embodiment of the invention;

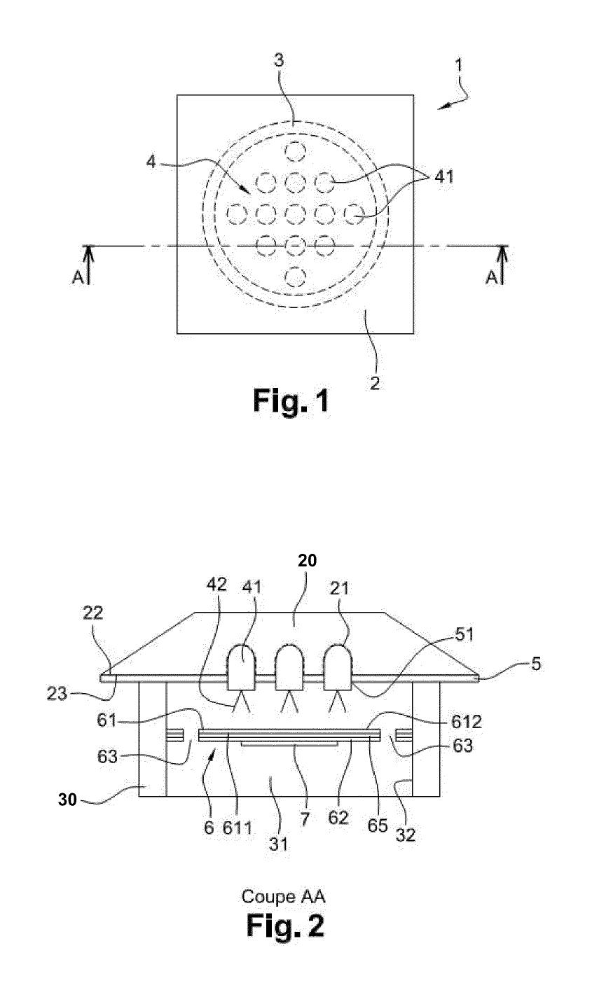

FIG. 2, a cross-sectional view of the lighting device of FIG. 1 according to one embodiment;

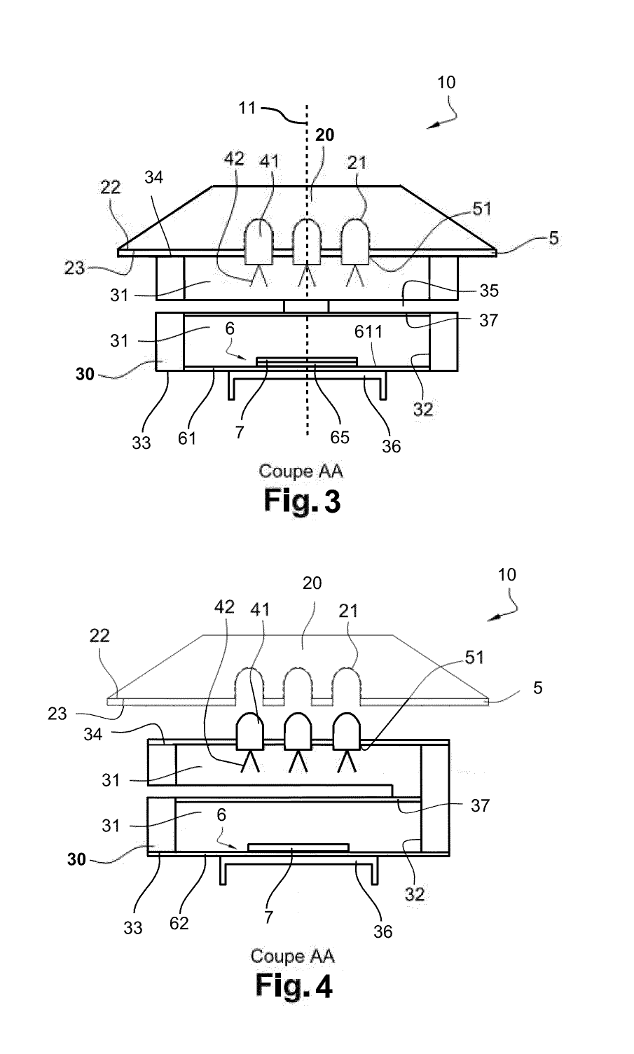

FIG. 3, a cross-sectional view of the lighting device of FIG. 1 according to another embodiment;

FIG. 4, a cross-sectional view of a lighting device, according to another embodiment.

A lighting device 10 according to one embodiment has—as illustrated in FIGS. 1 and 2:
a body 20;
a collar 30;
a lighting element 40 with a source of electric light 41 emitting a beam of light, and associated electrical connections 42.

The source of light 41 has at least one light-emitting diode—called LED. In the non-limitative illustration, FIG. 1, the source of light 41 has thirteen LEDs. The LEDs are positioned to emit light through the body 20.

The body 20 has a sufficient thickness to have, near the first side of said body—the back side 22—blind holes 21. The holes correspond in number, size and position to the number, size and position of the LEDs. Each blind hole 21 holds and keeps all or part of the LED in place.

In another embodiment, the body has open through-holes. The holes correspond in number, size and position to the number, size and position of the LEDs. Each through-hole holds and keeps in place a part of the LED, a part of the source of light from the body. The LEDs are then mounted through the body.

The body 20 is advantageously made in a transparent or translucent material, such as polycarbonate, to allow a diffusion of the light emitted by the LEDs. Said body offers significant impact resistance and is intended to withstand loads of at least 20 kgN.

In one embodiment, the body is a hollow body.

In one embodiment, the body has a non-limitative thickness of 5 cm.

Advantageously, the lighting device 10 has, on its back side 22, a first sheet with high thermal diffusivity 5, to allow the dissipation of the heat generated by the LEDs when the LEDs are in operation.

Preferably, the first high thermal diffusivity sheet 5 is made in a material with high conductivity and diffusivity coefficients such as example, an aluminum alloy. The first high thermal diffusivity sheet preferably has a thermal diffusivity of at least 0.83.104 m2/s and a thermal conductivity coefficient of at least 200 W/(m K).

The first high thermal diffusivity sheet 5 has openings 51 corresponding in number, size and position, to the number, size and position of the LEDs.

In one embodiment of the body 20, said body has on its back side 22, between this back side and the first high thermal diffusivity sheet 5, a coat of paint 23 to customize the end lighting device.

In another embodiment of the body 20, this body has on its back side 22 between this back side and the first high thermal diffusivity sheet 5 a reflective layer, advantageously a coat of light-colored lacquered paint that has good light-reflecting properties.

The collar 30 is mounted around the LEDs so that the electrical connections 42 of the LEDs are in an internal volume delineated by an internal wall 32 of the collar and the back side 22 of the body 20. The collar is held in place on the first high thermal diffusivity sheet 5 by the somewhat tight fit of the LEDs in the holes of the first high thermal diffusivity sheet and the blind holes of the body 20.

In a preferred non-limitative embodiment of the invention and as illustrated in the figures, the collar 30 has a cylindrical form, with a circular cross-section.

This embodiment is in and of itself non-limitative and those acquainted with the art can adapt the form of the collar to different shapes without departing from the realm of the invention.

Preferably, the collar 30 is made in a corrosion-resistant material, particularly saltwater, for example in polyvinyl chloride, acrylic or aluminum.

The lighting device 10 further has a regulator 7 in its internal volume and associated electronic components connected to the electrical connections 42 by thin cables (not shown).

The regulator 7 is fastened to a rigid support 6 to keep it in place.

In one embodiment of the support 6, this support 6 has a rigid plate 61. On one side 611 of the rigid plate 61 a sheet 65 of a thermal and electrical insulating material such as polyester is held, for example, by gluing. A second high thermal diffusivity sheet 62 is maintained on the insulating material 65, for example, by gluing, on which the regulator 7 is held. The second high thermal diffusivity sheet 62 allows the dissipation of the heat generated by the regulator 7.

The second high thermal diffusivity sheet 62 preferably has a thermal diffusivity coefficient of at least 0.83.104 m2/s and a thermal conductivity coefficient of at least 200 W/(m K).

Preferably, the assembly insulating sheet 65, the second high thermal diffusivity sheet 62 and the regulator 7 are placed on the side of the surface 611 of the rigid plate opposite a side 612 across from the LEDs. This position makes it possible on one hand to diffuse the heat from the regulator 7 to the environment outside the lighting device rather than to the LEDs and on the other, to prevent any electrical contact of the regulator 7 when the support 6 is placed in the collar 30.

In one embodiment of the support, the support does not have a rigid plate 61 and the insulating material sheet 65 is sufficiently rigid that it can hold the regulator 7 itself. The second high thermal diffusivity sheet 62 is glued to the sheet 65 in an insulating material on the side of the said insulating material opposite the LEDs.

In a preferred non-limitative embodiment of the invention, the support 6 is circular, the diameter noticeably equal to the inside diameter of the collar 30, so the support can be fitted tightly within the collar 30. The support 6 is kept inside the collar, for example by glue points, near a peripheral edge of the support.

The support 6 has in its thickness at least two through-openings 63 making communication possible of the two spaces that form the internal volume. The openings are of sufficient dimensions to allow the passage of the thin electrical cables.

In another embodiment of the support 6, illustrated in FIG. 3, the support 6 has a rigid plate 61. On one side 611 of the rigid plate 61, a sheet 65 of a thermal and electrical insulating material such as polyester or mica is maintained, for example by gluing. The regulator 7 is maintained on the sheet in thermally and electrically insulating material 65, for example by gluing or screwing, said sheet allowing the dissipation of the heat generated by the regulator 7.

In one embodiment, the sheet in thermally and electrically insulating material 65 and the regulator 7 are placed on the side of the surface 611 of the rigid plate, on the internal volume side of the collar 30.

Preferably, the rigid plate 61 is circular, with a diameter noticeably equal to the inside diameter of the collar 30, so the collar can be fitted tightly inside the collar. The collar is maintained inside the collar, for example by glue points, near a peripheral edge of said plate.

In another embodiment, illustrated in FIG. 4, the support 6 is a second high thermal diffusivity sheet 62, on a side 611 of which the regulator 7 is maintained, inside the volume of the collar 30. The second high thermal diffusivity sheet is intended to dissipate the heat generated by the regulator 7.

The second high thermal diffusivity sheet preferably has a thermal diffusivity coefficient of at least 0.83.104 m2/s and a thermal conductivity coefficient of at least 200 W/m K).

The second high thermal diffusivity sheet 62 and the regulator 7 are maintained fixed to each other, for example by gluing or screwing.

Preferably, the second high thermal diffusivity sheet 62 is positioned at one lateral end 33 opposite a lateral end 34 located on the back side 22 of the body 20. Thus, the second high thermal diffusivity sheet 62 benefits from a surface—not included in the internal volume of the collar 30, therefore in the open—to more effectively participate in the cooling of the device.

In one embodiment, the second high thermal diffusivity sheet 62 is circular, with a diameter noticeably equal to the inside diameter of the collar 30, so the second sheet can be fitted tightly inside the collar. The second high thermal diffusivity sheet 62 is kept inside the collar, by example by glue points, near a peripheral edge of the sheet.

In one preferred embodiment of the invention, the second high thermal diffusivity sheet 62 is circular, with a diameter noticeably equal to the outside diameter of the collar 30, so the said sheet can be maintained against the lateral end 33 of the collar. The second sheet 62 is maintained inside the collar, for example, by gluing near the lateral end 33 of the collar.

Preferably, the regulator 7 and the electronic components associated (not shown) are selected so they can be powered by a voltage of 12-24 V.

Preferably, the regulator 7 and the associated electronic components are chosen so once the electrical connection has been made, the lighting device 10 has a minimum footprint.

In one embodiment of an electrical connection, the LEDs are arranged in series of three, powered by a continuous voltage between 10 and 28 volts, using a regulator, for example, a LM-317-type regulator made by National Semiconductor, and a variable resistance on the order of 10 ohms.

A cable (not shown) to power the LEDs 41, is connected to the regulator 7 and to the associated electronic components, and passes through and extends outside of said internal volume.

The internal volume is filled with resin 31 in order to ensure that all the elements (electrical connections 42 of the LEDs, regulator 7, electronic components, cables) of the lighting device 10 are water-tight, and that the space between the first high thermal diffusivity sheet 5 and the collar 30 is also water-tight.

The openings 63, described in the first embodiment illustrated in FIG. 2, besides makes it possible for thin cables to pass through, also makes it possible for resin to flow in the space between the body 20 and the support 6 and for air initially contained in that space to be evacuated, when the internal volume is being filled.

Preferably, the resin 31 is an epoxy resin that is compatible with the various materials that make up the lighting device 10.

The first high thermal diffusivity sheet 5 covers the entire surface of the back side 22 of the body 20. This covering makes it possible—after the collar 30 is assembled and the resin 31 is injected—to benefit from a larger surface in the open and to participate in the cooling of the device.

In an alternative embodiment, the first high thermal diffusivity sheet 5 does not cover the entire back side 2 of the body 20. The first high thermal diffusivity sheet 5 has a surface strictly larger than the maximum transversal dimension of the collar 30, i.e., the external diameter in the preferred form of embodiments of said collar, so that after the collar 30 is assembled and the resin 31 is injected, the first high thermal diffusivity sheet 5 benefits from a part of its surface in the open to more effectively participate in the cooling of the lighting device.

In a special embodiment of the lighting device said device has a cooling chamber formed by an air-filled radial cavity 35 inside the resin.

This cavity thus makes it possible to let the air circulate and to contribute to the cooling of the device and to prevent heat from the regulator from being conducted to the LEDs.

In one embodiment of the cavity, said cavity is formed directly in the resin.

In another example of embodiment of the cavity, said cavity is delineated by a wall formed in the internal volume of the collar 30.

Preferably, the lighting device has two symmetrical cavities 35 with respect to a radial axis 11 of the device.

In other embodiment, the internal volume of the collar is separated into two volumes, a first volume contains the electrical connections of the LEDs and is filled with resin; the second volume contains the regulator 7 and is filled with resin. The second volume has a wall 37 making it possible to contain the resin in the second volume when it is being filled. The wall 37 is circular, with a diameter noticeably equal to the inside diameter of the collar 30, so the wall 37 can for example be tightly fitted inside the collar. The wall 37 is maintained inside the collar, for example, by glue points, near the peripheral edge of the wall. The wall is for example made of a material such as polycarbonate.

In another embodiment, illustrated in FIG. 4, the internal volume of the collar is separated into two volumes, the first volume contains the electrical connections of the LEDs and filled with resin; the second volume contains the regulator 7 and is filled with resin. The separation is a transversal cut of the collar, for example at two thirds of its diameter so the two volumes are not connected to each other over a portion of the wall of the collar, making it possible for electrical wires connecting the LEDs and the regulator and the associated components to pass through. The second volume has a wall 37 which makes it possible to contain the resin in the second volume when it is being filled. The wall 37 is circular and has a diameter noticeably equal to the inside diameter of the collar 30, so the wall 37 can for example be tightly fitted inside the collar.

The wall 37 is maintained inside the collar, for example, by glue points, near the peripheral edge of the wall. The wall is for example made of a material such as polycarbonate.

Thus, by means of these two separate volumes, it is possible to dissociate the various sources of heat 3, 7 and to more effectively cool the lighting device. Heat from the regulator 7 is prevented from being conducted to the LEDs 3 and vice versa. Moreover, each source of heat 3 and 7, respectively, is associated to and held against a high thermal diffusivity sheet 5 and 62, respectively.

In one embodiment, the collar has at the lateral end 34 located on the side of the body 20, a third high thermal diffusivity sheet 8 to allow the dissipation of the heat generated by LEDs when the LEDs are in operation. The lighting device 1 thus has—between the first sheet high thermal diffusivity 5 and the lateral end 34 located on the side of the body—a third high thermal diffusivity sheet 8.

The third high thermal diffusivity sheet 8 allows a possible dissociation of the body and the collar all while allowing the dissipation of the heat generated by the LEDs when the LEDs are in operation, even in the temporary absence of the body 20.

Thermal conductivity is provided by the contact between the first high thermal diffusivity sheet 5 and the third high thermal diffusivity sheet 8.

Preferably, the third high thermal diffusivity sheet 8 is made in a material with high thermal diffusivity and conductivity coefficients such as for example an aluminum alloy. The third high thermal diffusivity sheet preferably has a thermal diffusivity coefficient of at least 83.1.0 m2/s and a thermal conductivity coefficient of at least 200 W/(m K).

The third high thermal diffusivity sheet 8 has openings corresponding, in number, size and position, to the number, size and position of the LEDs.

In one embodiment, the third high thermal diffusivity sheet 8 is circular whose diameter is noticeably equal to the inside diameter of the collar 30, so the third sheet can be tightly fitted inside the collar. The third sheet with high thermal diffusivity 8 is maintained inside the collar, for example, by glue points, near the peripheral edge of that sheet.

In a preferred embodiment, the third high thermal diffusivity sheet 8 is circular, with a diameter noticeably equal to the outside diameter of the collar 30, so the said third sheet can be maintained against the lateral end 34 of the collar. The third sheet 8 is maintained outside the collar, for example by gluing it near the lateral end 34 of the collar.

The collar is maintained fixed on the first high thermal diffusivity sheet 5 and the body 20, by fitting the LEDs tightly inside the openings of the first high thermal diffusivity sheet and the blind holes of the body 20.

The collar and the body can thus be made independently of each other. The body is made detachable with respect to the collar, for example, to meet mechanical restrictions or to fulfill a special required aesthetic aspect. The body can thus be interchangeable in its form, color and its thickness.

In another embodiment, of the lighting device, in order to dissipate the heat, this device further has outside the collar 30, near the lateral end 33, a plate for dissipating heat 36. Preferably, the plate 36 is for example screwed or glued to the support 6 or the second high thermal diffusivity sheet 62, depending on the selected production mode.

In one embodiment, the plate 36 is a U-shaped plate, as illustrated in FIG. 2.

In another embodiment, the plate 36 is a finned plate, with the fins being directed outside of the device.

To make the lighting device 10 of the invention according to the embodiment of FIG. 1, the body 20 is prepared in a first stage.

The body 20 is cut—for example by machining—to the desired dimensions for the lighting device. The dimensions are preferably defined as a function of the number of LEDs to be positioned in said lighting device.

Optionally, a coat of paint 23 is applied to the back side 22 of the body 20 in order to obtain the desired color for the lighting device. Preferably, the color is chosen so it does not diminish the lighting power of the LEDs when they are in operation.

In a subsequent phase, the first high thermal diffusivity sheet 5 is maintained on the body 20.

In one embodiment, a first phase consists of cutting the first high thermal diffusivity sheet 5 to the dimensions of the back side 22 of the body. 20. A second phase consists then of maintaining the first high thermal diffusivity sheet 5 in position on the back side. This for example can be done by gluing.

When the first high thermal diffusivity sheet 5 and the body 20 are maintained together, the entire unit is machined to make the blind holes 21 to receive the LEDs 41.

The LEDs are set in the blind holes 21 by example by embedding or gluing them.

It is also possible to form holes to receive the LEDs 41, by machining the first high thermal diffusivity sheet 5 and the body separately and then assembling them.

The LEDs 41 are then connected to each other, by electrical connections 42, by means of thin cables which are then connected to the regulator 7 and to the associated electronic components.

The regulator 7 was assembled beforehand, for example, by gluing the insulating material 65 and the second high thermal diffusivity sheet 62 of the support 6 pre-cut to the desired dimensions.

The support 6 is pre-machined to make at least two through-openings 63 to pass the thin wires.

The power cable is connected to the LEDs 41, regulator 7 and associated electronic components.

The collar 30 is then assembled, for example, by gluing it to the back side 22 of the body 20.

The support 6 is subsequently positioned inside the collar 30 and maintained inside said collar by a radial tightening and by glue points near the peripheral edge of the support 6.

In a last phase, the resin 31 is injected into the internal volume delineated by the internal wall 32 of the collar 30 and the back side 22 of the body 20 so as to imprison all the constitutive elements of the lighting device 10 and a part of the power cable and to make said lighting device water-tight. The resin 31 is poured into the hollow space of the internal volume between the back side 22 of the body 20 and the support 6, by means of at least two through-holes 63 of the support 6. When the volume is filled with resin, the air in this space between the back side 22 of the body 20 and the support 6 is evacuated by at least two through-holes 63.

Advantageously, the resin is poured in a single time.

The production process of the lighting device 10 is described with the phases according to a certain order but persons acquainted with the art are capable of adapting the process by modifying the order of production of certain phases or by simultaneously carrying out certain phases in order to end up with the final lighting device.

The lighting device according to the invention thus has the advantage of being monolithic and of a similar constitution, of being entirely waterproof as a result of the resin making it possible to enclose all of the elements (electrical connections of the LEDs, regulator, electronic components, wiring) that constitute the lighting device on the back side of the body. The device has the advantage of being particularly well adapted to a use in a marine environment, for example on the walls of a swimming pool, in a boat, etc.

The device further has the advantage of being particularly shock-resistant and fire-resistant, as a result of the selection of the adapted resin materials.

1. A lighting device comprising:
a body of transparent or translucent material;
a collar mounted on a first side of the body and delineating a first volume filled with a resin;
a lighting element with an electrical light source and associated electrical connections;
wherein the electrical light source is partly maintained in the body in which the electrical connections are located in the resin-filled first volume, in which the lighting device has a first high thermal diffusivity layer sheet maintained against the first side of the body in order to allow the dissipation of heat generated by the electrical light source, and wherein the lighting device has a regulator maintained against a second high thermal diffusivity sheet to allow the dissipation of heat generated by the regulator.

2. The lighting device of claim 1, wherein the first high thermal diffusivity sheet has a surface strictly larger than a maximum transversal dimension of the collar.

3. The lighting device of claim 1, wherein the first high thermal diffusivity sheet covers a back side of the body.

4. The lighting device of claim 1, wherein the second high thermal diffusivity sheet is positioned at a first lateral end opposite a second lateral end located on a back side of the body.

5. The lighting device of claim 1, wherein the collar comprises a second volume, and wherein the regulator and the second high thermal diffusivity sheet are located in the second volume.

6. The lighting device of claim 1, wherein the collar has a third high thermal diffusivity sheet at one lateral end located on the side of the collar nearest the body.

7. The lighting device of claim 1, wherein the electrical light source has at least one light-emitting diode.

8. The lighting device of claim 1, further comprising a plate for dissipating heat, the plate being located on the back side of the body, proximate to the first lateral end and opposite the second lateral end.

9. The lighting device, wherein the first high thermal diffusivity sheet comprises an aluminum alloy.

10. The lighting device, wherein the body is detachable with respect to the collar.
